(19) United States
(12) Patent Application Publication
(10) Pub. No.: US 2026/0104747 A1
(43) Pub. Date: Apr. 16, 2026

(54) COMPUTING SYSTEM ADJUSTING POWER VOLTAGE

(71) Applicant: SK hynix Inc., Icheon-si Gyeonggi-do (KR)

(72) Inventor: Gun Hee LEE, Icheon-si Gyeonggi-do (KR)

(73) Assignee: SK hynix Inc., Icheon-si Gyeonggi-do (KR)

(21) Appl. No.: 19/066,429

(22) Filed: Feb. 28, 2025

(30) Foreign Application Priority Data
Oct. 10, 2024 (KR) 10-2024-0137813

(51) Int. Cl. G06F 1/26; G11C 5/14

(52) U.S. Cl. CPC G06F 1/26; G11C 5/147

(57) ABSTRACT

A computing system includes a power supply, a main voltage regulator, a processor, and a memory module. The power supply is configured to generate a first input voltage and a second input voltage. The main voltage regulator is configured to generate a processor power voltage from the first input voltage. The memory module includes a power management integrated circuit that generates a memory power voltage from the second input voltage. The power management integrated circuit is configured to adjust the voltage level of the memory power voltage based on the processor power voltage and the memory power voltage.

### CROSS-REFERENCES TO RELATED APPLICATION

The present application claims priority under 35 U.S.C. § 119(a) to Korean Patent Application No. 10-2024-0137813, filed in the Korean Intellectual Property Office on Oct. 10, 2024, the entire contents of which application is incorporated herein by reference.

### BACKGROUND

### 1. Technical Field

Various embodiments relate to a computing system, and particularly, to a computing system capable of adjusting the voltage level of a power voltage.

### 2. Related Art

An electronic device includes many electronic components. A computing system, among the electronic components, may include many semiconductor devices including a semiconductor. The semiconductor devices that constitute the computing system may communicate with each other by transmitting and receiving system clock signals and data. The computing system may receive power from a power supply and supply the operation voltages of the semiconductor devices that constitute the computing system. A common computing system may include a main board, a processor, and a memory module. The processor and the memory module may be mounted on the main board. A voltage regulator may be formed in the main board. The voltage regulator may receive the power from the power supply and may generate a power voltage that is provided to the memory module and a power voltage that is provided to the processor by converting the power.

As the semiconductor technique is advanced, the operation voltages of semiconductor devices continue to be lowered. The memory module may include a power management integrated circuit to provide stable operation voltages to a plurality of memory devices mounted on the memory module. The power management integrated circuit may generate a memory power voltage supplied from the power supply and may provide the memory power voltage to the plurality of memory devices. The memory devices may use a plurality of memory power voltages. The processor may also use a plurality of processor power voltages. The plurality of memory power voltages and the plurality of processor power voltages may have independent voltage levels. However, a memory power voltage and a processor power voltage for driving a signal that is used in bidirectional communication like a data signal may have the same voltage level. However, there may be a voltage level difference between the memory power voltage and the processor power voltage because the memory power voltage is generated by the power management integrated circuit and the processor power voltage is generated by the voltage regulator. The voltage level difference may reduce operation performance of the computing system.

### SUMMARY

In an embodiment, a computing system may include a power supply, a main voltage regulator, a processor, and a memory module. The power supply may be configured to generate a first input voltage and a second input voltage. The main voltage regulator may be configured to generate a processor power voltage based on the first input voltage. The processor may be configured to receive the processor power voltage. The memory module may be configured to communicate with the processor. The memory module may include at least one memory device and a power management integrated circuit. The power management integrated circuit may be configured to receive the second input voltage and the processor power voltage, to generate a memory power voltage based on the second input voltage and memory power voltage setting information, to provide the memory power voltage to the at least one memory device, and to change the memory power voltage setting information based on comparing the memory power voltage to the processor power voltage.

In an embodiment, a computing system may include a power supply, a main voltage regulator, a processor, and a memory module. The power supply may be configured to generate a first input voltage and a second input voltage. The main voltage regulator may be configured to generate a processor power voltage based on the first input voltage. The processor may be configured to receive the processor power voltage. The memory module may be configured to communicate with the processor. The memory module may include at least one of memory device and a power management integrated circuit. The power management integrated circuit may be configured to generate a memory power voltage based on the second input voltage and memory power voltage setting information, to provide the memory power voltage to the at least one memory device, and to change the memory power voltage setting information based on a voltage adjustment signal. The processor may be configured to generate the voltage adjustment signal based on the processor power voltage and the memory power voltage.

In an embodiment, a computing system may include a power supply, a main voltage regulator, a processor, a memory module, and a system controller. The power supply may be configured to generate a first input voltage and a second input voltage. The main voltage regulator may be configured to generate a processor power voltage based on the first input voltage. The processor may be configured to receive the processor power voltage. The memory module may be configured to communicate with the processor. The system controller may be configured to communicate with the processor and the memory module. The memory module may include at least one memory device and a power management integrated circuit. The power management integrated circuit may be configured to generate a memory power voltage based on the second input voltage and memory power voltage setting information, to provide the memory power voltage to the at least one memory device, and to change the memory power voltage setting information based on a voltage adjustment signal. The system controller may be configured to generate the voltage adjustment signal based on the processor power voltage and the memory power voltage.

### BRIEF DESCRIPTION OF THE DRAWINGS

FIG. 1 is a diagram illustrating a configuration of a computing system according to an embodiment.

FIG. 2 is a diagram illustrating a configuration of a computing system according to an embodiment.

FIG. 3 is a diagram illustrating a configuration of a computing system according to an embodiment.

FIG. 4 is a diagram illustrating a configuration of an embodiment of a power management integrated circuit illustrated in FIG. 3.

FIG. 5 is a diagram illustrating a configuration of a computing system according to an embodiment.

FIG. 6 is a diagram illustrating a configuration of a computing system according to an embodiment.

FIG. 7 is a diagram illustrating a configuration of a computing system according to an embodiment.

FIG. 8 is a diagram illustrating a configuration of a computing system according to an embodiment.

### DETAILED DESCRIPTION

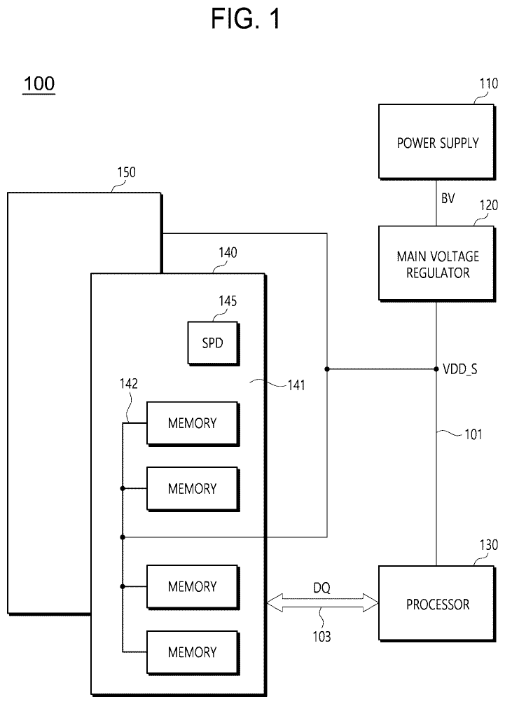

FIG. 1 is a diagram illustrating a configuration of a computing system 100 according to an embodiment. Referring to FIG. 1, the computing system 100 may include a power supply 110, a main voltage regulator 120, a processor 130, and a first memory module 140. The components of the computing system 100 may be coupled to a main board or a mother board or may be mounted on the main board or the mother board. Some of the components of the computing system 100 may be embedded in the main board or the mother board. The components of the computing system 100 may be coupled through a signal path and/or an interface circuit that is formed in the main board or the mother board. The power supply 110 may be a power source of the computing system 100. The power supply 110 may receive power from an external source and may generate a plurality of supply voltages by converting the power into a voltage and a current that are suitable for being used in the components of the computing system 100. For example, the power supply 110 may generate an input voltage BV and may provide the input voltage BV to the main voltage regulator 120. The computing system 100 may be applied as at least one of a desktop computer, a laptop computer, a server, a workstation, a mobile device, and a graphic device. The input voltage BV may have various voltage levels depending on an application of the computing system 100. For example, the voltage level of the input voltage BV may be any one of voltage levels 3.3 V, 5 V, and 12 V; however, the disclosure is not limited thereto.

The main voltage regulator 120 may receive the input voltage BV from the power supply 110. The main voltage regulator 120 may use the input voltage BV as operating power and may generate a plurality of system supply voltages. For example, the main voltage regulator 120 may generate a system power voltage VDD_S by regulating the input voltage BV. The system power voltage VDD_S may be a voltage that is used in the processor 130 and the first memory module 140 in common. For example, the system power voltage VDD_S may be a voltage that is used for the processor 130 and the first memory module 140 to perform data communication. The main voltage regulator 120 may supply the system power voltage VDD_S to the processor 130 and the first memory module 140. The main voltage regulator 120 may be coupled to the processor 130 and the first memory module 140 through a system power supply line 101 and may provide the system power voltage VDD_S to the processor 130 and the first memory module 140 through the system power supply line 101. In an embodiment, by regulating the input voltage BV, the main voltage regulator 120 may generate the system supply voltage that is used only in the processor 130 and may generate the system supply voltage that is used only in the first memory module 140. For example, each of the plurality of system supply voltages may have at least one voltage level, among voltage levels of 0.7 V, 0.85 V, 1.0 V, 1.1 V, 1.125 V, 1.25 V, 1.8 V, 1.83 V, and 3.3 V; however, the disclosure is not limited thereto. For example, the system power voltage VDD_S may have a voltage level of 1.0 V or 1.1 V.

The processor 130 may communicate with the first memory module 140. The processor 130 may receive the system power voltage VDD_S from the main voltage regulator 120 through the system power supply line 101 and may operate by using the system power voltage VDD_S. The processor 130 may be a host device capable of accessing the first memory module 140 to perform various calculation operations. For example, the processor 130 may include at least one of a central processing unit (CPU), a graphic processing unit (GPU), a multi-media processor (MMP), a digital signal processor, an application processor (AP), a data processing unit (DPU), a neural processing unit (NPU), a system-on chip (SoC), and a memory controller or a combination of two or more of them. The processor 130 may be coupled to the first memory module 140 through a data bus 103, may transmit data DQ to the first memory module 140 through the data bus 103, and may receive the data DQ transmitted by the first memory module 140 through the data bus 103. The processor 130 may transmit the data DQ to the first memory module 140 by driving the data bus 103 to the system power voltage VDD_S. Although not illustrated, the processor 130 may be coupled to the first memory module 140 through a clock bus, a command bus, an address bus, or a command address bus to access the first memory module 140.

The first memory module 140 may communicate with the processor 130. The first memory module 140 may receive the system power voltage VDD_S from the main voltage regulator 120 through the system power supply line 101 and may operate by using the system power voltage VDD_S. The processor 130 may control the first memory module 140 to perform a data input operation and a data output operation. The data input operation may be a write operation of the data DQ being transmitted from the processor 130 to the first memory module 140 and the first memory module 140 storing the data DQ. The data output operation may be a read operation of data, which have been stored in the first memory module 140, being output to the processor 130 as the data DQ. The first memory module 140 may be coupled to the processor 130 through the data bus 103, may transmit the data DQ to the processor 130 through the data bus 103, and may receive the data DQ transmitted by the processor 130 through the data bus 103. The first memory module 140 may transmit the data DQ to the processor 130 by driving the data bus 103 to the system power voltage VDD_S. Although not illustrated, the first memory module 140 may be coupled to the processor 130 through the clock bus, the command bus, the address bus, or the command address bus. The computing system 100 may include one or more memory modules. In an embodiment, the computing system 100 may further include a second memory module 150. The second memory module 150 may have substantially the same configuration as the first memory module 140 and may be coupled to the components of the computing system 100 in substantially the same manner as the first memory module 140. In an embodiment, the computing system 100 may include three or more memory modules.

The first memory module 140 may include at least one memory. For example, the first memory module 140 may include four memory devices. The memory devices may be a packaged memory device and may constitute the first memory module 140 by being mounted on a memory module substrate 141. The memory devices may provide the memory capacity and/or memory density of the first memory module 140. The memory devices included in the first memory module 140 may include volatile memory and nonvolatile memory. At least one of the memory devices may be a different type of memory, and the rest of the memory devices may be the same type of memory. The memory devices may be coupled to the main voltage regulator 120 through the system power supply line 101 and may receive the system power voltage VDD_S from the main voltage regulator 120. The system power supply line 101 may be coupled to a memory power supply line 142. The system power voltage VDD_S may be transmitted from the main voltage regulator 120 to the first memory module 140 through the system power supply line 101 and may be distributed to the memory devices through the memory power supply line 142 within the first memory module 140. The data DQ transmitted from the processor 130 to the first memory module 140 through the data bus 103 may be input to the memory devices. The memory devices may store the data DQ. Data output from the memory devices may be transmitted to the processor 130 through the data bus 103 as the data DQ. The memory devices may drive the data bus 103 with the system power voltage VDD_S to transmit the data DQ.

The first memory module 140 may further include a serial presence detect (SPD) 145. The SPD 145 may be a register or a small memory device that stores information related to a memory module. The SPD 145 may store information, such as the memory capacity, clock speed, operation voltage, and driver strength of the first memory module 140, manufacturing information of the memory module, and manufacturing information of memory devices, and may provide the stored information to the processor 130.

The system power voltage VDD_S may be a voltage that is used to drive the data DQ transmitted through the data bus 103. It may be preferred that a voltage level of the data bus 103 that is driven by the first memory module 140 and a voltage level of the data bus 103 that is driven by the processor 130 to guarantee performance of the computing system 100 are the same or have at least an error within a tolerance range. However, a difference inevitably occurs between an actual voltage level of the system power voltage VDD_S that is received by the processor 130 and an actual voltage level of the system power voltage VDD_S that is received by the first memory module 140 due to a physical distance difference from the main voltage regulator 120 to the processor 130 and the first memory module 140. When a difference between the actual voltage levels of the system power voltages VDD_S that are used by the processor 130 and the first memory module 140 falls outside the tolerance range, a communication error may occur because the swing range of the data DQ transmitted through the data bus 103 is changed.

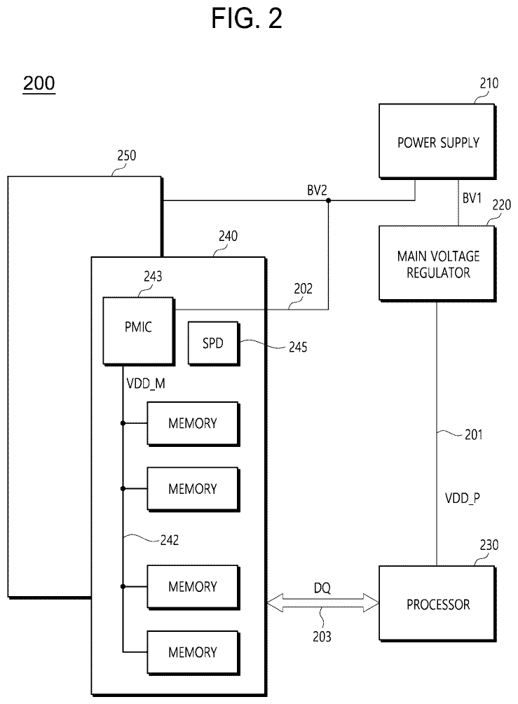

FIG. 2 is a diagram illustrating a configuration of a computing system 200 according to an embodiment. Referring to FIG. 2, the computing system 200 may include a power supply 210, a main voltage regulator 220, a processor 230, and a first memory module 240. Hereinafter, descriptions of the components of the computing system 200 that are identical or redundant to the descriptions of the components of the computing system 100 illustrated in FIG. 1 may be omitted. The power supply 210 may generate a first input voltage BV1 and a second input voltage BV2 by receiving power from an external source. The power supply 210 may provide the first input voltage BV1 to the main voltage regulator 220. The power supply 210 may provide the second input voltage BV2 to the first memory module 240. The second input voltage BV2 may have the same voltage level as the first input voltage BV1 or may have a voltage level different from that of the first input voltage BV1. The main voltage regulator 220 may receive the first input voltage BV1 and generate a processor power voltage VDD_P by regulating the first input voltage BV1. The processor power voltage VDD_P may be a voltage that may be dedicatedly used in the processor 230. The processor power voltage VDD_P may have the same characteristics as the system power voltage VDD_S illustrated in FIG. 1. The main voltage regulator 220 may be coupled to the processor 230 through a processor power supply line 201 and may provide the processor power voltage VDD_P to the processor 230 through the processor power supply line 201.

The processor 230 may communicate with the first memory module 240. The processor 230 may receive the processor power voltage VDD_P from the main voltage regulator 220 through the processor power supply line 201 and may operate by using the processor power voltage VDD_P. The processor 230 may be coupled to the first memory module 240 through a data bus 203, may transmit data DQ to the first memory module 240 through the data bus 203, and may receive data DQ transmitted by the first memory module 240 through the data bus 203. The processor 230 may transmit the data DQ to the first memory module 240 by driving the data bus 203 with the processor power voltage VDD_P.

The first memory module 240 may communicate with the processor 230. The first memory module 240 may receive the second input voltage BV2 and may generate a memory power voltage VDD_M from the second input voltage BV2. The first memory module 240 may operate by using the memory power voltage VDD_M. The target voltage level of the memory power voltage VDD_M may be the same as the target voltage level of the processor power voltage VDD_P. The first memory module 240 may be coupled to the processor 230 through the data bus 203, may transmit the data DQ to the processor 230 through the data bus 203, and may receive the data DQ transmitted by the processor 230 through the data bus 203. The first memory module 240 may transmit the data DQ to the processor 230 by driving the data bus 203 to the memory power voltage VDD_M. The computing system 200 may include one or more memory modules. In an embodiment, the computing system 200 may further include a second memory module 250. The second memory module 250 may have substantially the same configuration as the first memory module 240 and may be coupled to the components of the computing system 200 in substantially the same manner as the first memory module 240. In an embodiment, the computing system 200 may include three or more memory modules.

The first memory module 240 may include a power management integrated circuit (PMIC) 243 and at least one memory device. The PMIC 243 may receive the second input voltage BV2 from the power supply 210. The PMIC 243 may generate the memory power voltage VDD_M from the second input voltage BV2. The PMIC 243 may store memory power voltage setting information related to the target voltage level of the memory power voltage VDD_M. The memory power voltage setting information may be stored in a register of the PMIC 243. The PMIC 243 may generate the memory power voltage VDD_M from the second input voltage BV2 based on the memory power voltage setting information. The PMIC 243 may supply and/or distribute the memory power voltage VDD_M to the at least one memory device included in the first memory module 240. For example, the PMIC 243 may provide the memory power voltage VDD_M to at least one memory device through the memory power supply line 242.

For example, the first memory module 240 may include four memory devices. The memory devices may be coupled to the PMIC 243 through the memory power supply line 242 and may receive the memory power voltage VDD_M from the PMIC 243 through the memory power supply line 242. The memory devices may operate by using the memory power voltage VDD_M. The data DQ transmitted from the processor 230 to the first memory module 240 through the data bus 203 may be input to the memory devices. The memory devices may store the data DQ. Data output from the memory devices may be transmitted to the processor 230 through the data bus 203 as the data DQ. The memory devices may drive the data bus 203 with the memory power voltage VDD_M to transmit the data DQ. The first memory module 240 may further include a serial presence detect (SPD) 245.

The first memory module 240 may include the PMIC 243 and may generate the memory power voltage VDD_M independently of the processor power voltage VDD_P. The first memory module 240 can reduce a voltage level difference between the power voltages that may be actually received by the processor 230 and the first memory module 240 due to a physical distance difference from the main voltage regulator 220 to the processor 230 and the first memory module 240, which are illustrated in FIG. 2. However, the processor power voltage VDD_P and the memory power voltage VDD_M may have an error greater than a threshold range due to a process variation because the PMIC 243 of the first memory module 240 and the main voltage regulator 220 are manufactured through different processes and the processor power voltage VDD_P and the memory power voltage VDD_M do not have a correlation.

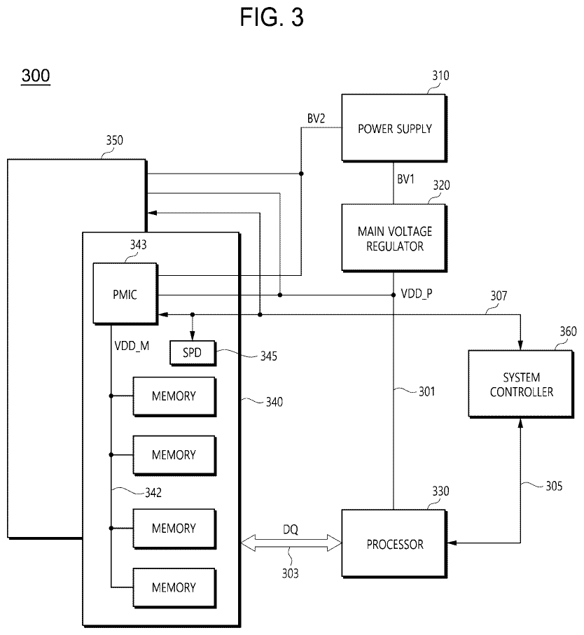

FIG. 3 is a diagram illustrating a configuration of a computing system 300 according to an embodiment. Referring to FIG. 3, the computing system 300 may include a power supply 310, a main voltage regulator 320, a processor 330, and a first memory module 340. The power supply 310 may generate a first input voltage BV1 and a second input voltage BV2 by receiving power from an external source. The power supply 310 may provide the first input voltage BV1 to the main voltage regulator 320 and may provide the second input voltage BV2 to the first memory module 340. The main voltage regulator 320 may receive the first input voltage BV1 and may generate a processor power voltage VDD_P from the first input voltage BV1. The main voltage regulator 320 may be coupled to the processor 330 through a processor power supply line 301 and may provide the processor power voltage VDD_P to the processor 330 through the processor power supply line 301.

The processor 330 may communicate with the first memory module 340. The processor 330 may receive the processor power voltage VDD_P from the main voltage regulator 320 through the processor power supply line 301 and may operate by using the processor power voltage VDD_P. The processor 330 may be coupled to the first memory module 340 through a data bus 303, may transmit data DQ to the first memory module 340 through the data bus 303, and may receive data DQ transmitted by the first memory module 340 through the data bus 303. The processor 330 may transmit the data DQ to the first memory module 340 by driving the data bus 303 with the processor power voltage VDD_P.

The first memory module 340 may communicate with the processor 330. The first memory module 340 may receive the second input voltage BV2 and may generate a memory power voltage VDD_M from the second input voltage BV2. The first memory module 340 may operate by using the memory power voltage VDD_M. A target voltage level of the memory power voltage VDD_M may be the same as a target voltage level of the processor power voltage VDD_P. The first memory module 340 may be coupled to the processor 330 through the data bus 303, may transmit data DQ to the processor 330 through the data bus 303, and may receive data DQ from the processor 330 through the data bus 303. The first memory module 340 may transmit the data DQ to the processor 330 by driving the data bus 303 to the memory power voltage VDD_M. The computing system 300 may include one or more memory modules. In an embodiment, the computing system 300 may further include a second memory module 350. The second memory module 350 may have substantially the same configuration as the first memory module 340 and may be coupled to the components of the computing system 300 in substantially the same manner as the first memory module 340. In an embodiment, the computing system 300 may include three or more memory modules.

To adjust an error between the processor power voltage VDD_P and the memory power voltage VDD_M, the first memory module 340 may be additionally coupled to a processor power supply line 301 and may receive the processor power voltage VDD_P through the processor power supply line 301. The first memory module 340 may compare the voltage level of the processor power voltage VDD_P to the voltage level of the memory power voltage VDD_M and can reduce a voltage level difference between the the processor power voltage VDD_P and the memory power voltage VDD_M. For example, when a voltage level difference between the processor power voltage VDD_P and the memory power voltage VDD_M is outside of a threshold range, the first memory module 340 may adjust the voltage level of the memory power voltage VDD_M so that the voltage level difference between the memory power voltage VDD_M and the processor power voltage VDD_P is within the threshold range. For example, the threshold range may be about half a tolerance range. However, the disclosure is not limited thereto, and the tolerance range and the threshold range may be variously changed. For example, the tolerance range may correspond to about 10% of the target voltage level, and the threshold range may correspond to about 5% of the target voltage level. When the target voltage level of each of the processor power voltage VDD_P and the memory power voltage VDD_M is 1.1 V, the tolerance range of a voltage level difference between the processor power voltage VDD_P and the memory power voltage VDD_M may be about 0.11 V. In this case, the threshold range may be about 0.55 V.

The first memory module 340 may include a power management integrated circuit (PMIC) 343 and at least one memory. The PMIC 343 may receive the second input voltage BV2 from the power supply 310. The PMIC 343 may generate the memory power voltage VDD_M from the second input voltage BV2. The PMIC 343 may store memory power voltage setting information with regard to the target voltage level of the memory power voltage VDD_M. The memory power voltage setting information may be stored in a register of the PMIC 343. The PMIC 343 may generate the memory power voltage VDD_M from the second input voltage BV2 based on the memory power voltage setting information. The PMIC 343 may supply and/or distribute the memory power voltage VDD_M to memory included in the first memory module 340. The PMIC 343 may provide the memory power voltage VDD_M to the at least one memory through a memory power supply line 342. The PMIC 343 may be further coupled to the processor power supply line 301 and may receive the processor power voltage VDD_P through the processor power supply line 301. The PMIC 343 may compare the voltage level of the processor power voltage VDD_P to the voltage level of the memory power voltage VDD_M. When a voltage level difference between the processor power voltage VDD_P and the memory power voltage VDD_M is within a threshold range, the PMIC 343 may maintain the memory power voltage setting information and may continue to generate the memory power voltage VDD_M based on the memory power voltage setting information. When a voltage level difference between the processor power voltage VDD_P and the memory power voltage VDD_M is outside of the threshold range, the PMIC 343 may modify the memory power voltage setting information. For example, when a voltage level difference between the processor power voltage VDD_P and the memory power voltage VDD_M is outside of the threshold range and the processor power voltage VDD_P has a higher voltage level than the memory power voltage VDD_M, the PMIC 343 may modify the memory power voltage setting information so that the voltage level of the memory power voltage VDD_M is increased. In contrast, when the processor power voltage VDD_P has a lower voltage level than the memory power voltage VDD_M, the PMIC 343 may modify the memory power voltage setting information so that the voltage level of the memory power voltage VDD_M is lowered. The PMIC 343 can compare the voltage level of the memory power voltage VDD_M to the voltage level of the processor power voltage VDD_P, generated by an independent voltage generator and can maintain a voltage level difference between the memory power voltage VDD_M and the processor power voltage VDD_P within the threshold range. Accordingly, performance of the computing system 300 can be improved by reducing a change in the swing range of the data DQ transmitted through the data bus 303 and by improving communication reliability between the first memory module 340 and the processor 330.

For example, the first memory module 340 may include four memory devices. The memory devices may be coupled to the PMIC 343 through the memory power supply line 342 and may receive the memory power voltage VDD_M from the PMIC 343 through the memory power supply line 342. The memory devices may operate by using the memory power voltage VDD_M. The data DQ transmitted from the processor 330 to the first memory module 340 through the data bus 303 may be input to the memory devices. The memory devices may store the data DQ. Data output from the memory devices may be transmitted to the processor 330 through the data bus 303 as the data DQ. The memory devices may drive the data bus 303 with the memory power voltage VDD_M to transmit the data DQ. The first memory module 340 may further include a serial presence detect (SPD) 345.

The computing system 300 may further include a system controller 360. The system controller 360 may be a component that is mounted on or embedded in a main board or a mother board. In general, the system controller 360 may perform a function that recognizes the physical number of memory modules mounted on or coupled to the main board or the mother board and sets system information. The system controller 360 may be coupled to the processor 330 and the first memory module 340 and may communicate with the processor 330 and the first memory module 340. The system controller 360 may be coupled to the processor 330 and the first memory module 340 by using a standard protocol. For example, the system controller 360 may be coupled to the processor 330 and the first memory module 340 through a serial peripheral interface (SPI) protocol, an inter-integrated circuit (I2C) protocol, or an improved inter-integrated circuit (I3C) protocol. In an embodiment, the system controller 360 may communicate with the processor 330 in synchronization with a rising edge of a clock signal and may communicate with the first memory module 340 in synchronization with a falling edge of the clock signal. The system controller 360 may be coupled to the processor 330 through a first signal transmission line 305 and may be coupled to the first memory module 340 through a second signal transmission line 307. The system controller 360 may be coupled to the SPD 345 of the first memory module 340 through the second signal transmission line 307. The PMIC 343, together with the SPD 345, may be coupled to the system controller 360 through the second signal transmission line 307, in common. If the PMIC 343, together with the SPD 345, is coupled to the system controller 360 through the second signal transmission line 307, a separate module pin that enables the PMIC 343 to be coupled to the system controller 360, among module pins included in the first memory module 340, might not be assigned to the PMIC 343. In other words, the number of available module pins might not be reduced because the PMIC 343 can be coupled to the system controller 360 through a module pin already assigned to the SPD 345. In an embodiment, a separate module pin may be assigned to the PMIC 343, and the PMIC 343 may be coupled to the system controller 360 independently of the SPD 345.

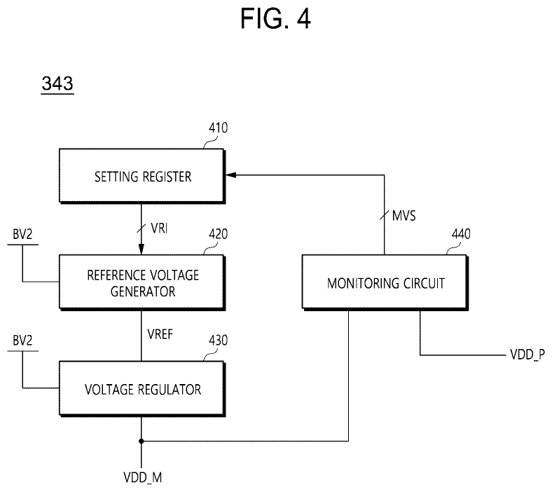

FIG. 4 is a diagram illustrating a configuration of the PMIC 343 illustrated in FIG. 3. Referring to FIG. 4, the PMIC 343 may include a setting register 410, a reference voltage generator 420, a voltage regulator 430, and a monitoring circuit 440. The setting register 410 may store memory power voltage setting information VRI. The memory power voltage setting information VRI may be a code signal including a plurality of bits. The setting register 410 may store a code value of the memory power voltage setting information VRI. The setting register 410 may store the memory power voltage setting information VRI in a process of manufacturing the PMIC 343. After the first memory module 340 is mounted on the computing system 100, the setting register 410 may receive the memory power voltage setting information VRI from the processor 330 or the system controller 360 and may store the memory power voltage setting information VRI. The setting register 410 may further receive a voltage adjustment signal MVS. The setting register 410 may modify the memory power voltage setting information VRI based on the voltage adjustment signal MVS. For example, the voltage adjustment signal MVS may be a digital signal including plural bits. The setting register 410 may change the code value of the memory power voltage setting information VRI based on a logic value of the voltage adjustment signal MVS. For example, when receiving the voltage adjustment signal MVS for raising the voltage level of the memory power voltage VDD_M, the setting register 410 may increase the code value of the memory power voltage setting information VRI. When receiving the voltage adjustment signal MVS for lowering the voltage level of the memory power voltage VDD_M, the setting register 410 may reduce the code value of the memory power voltage setting information VRI.

The reference voltage generator 420 may receive the memory power voltage setting information VRI from the setting register 410. The reference voltage generator 420 may receive the second input voltage BV2. The reference voltage generator 420 may generate a reference voltage VREF, based on the memory power voltage setting information VRI and the second input voltage BV2. For example, the reference voltage generator 420 may divide the second input voltage BV2 into a plurality of division voltages, may select one of the plurality of division voltages based on the memory power voltage setting information VRI, and may output the reference voltage VREF. The reference voltage generator 420 may adopt any voltage generator capable of generating a voltage signal having various voltage levels based on a digital code signal.

The voltage regulator 430 may receive the reference voltage VREF from the reference voltage generator 420 and may operate by receiving the second input voltage BV2. The voltage regulator 430 may generate the memory power voltage VDD_M, based on the second input voltage BV2 and the reference voltage VREF. The voltage regulator 430 may compare the voltage level of the reference voltage VREF to the voltage level of the memory power voltage VDD_M and may raise or lower the voltage level of the memory power voltage VDD_M based on the results of the comparison. When the voltage level of the memory power voltage VDD_M is lower than the voltage levels of the reference voltage VREF, the voltage regulator 430 may raise the voltage level of the memory power voltage VDD_M by driving the memory power voltage VDD_M to the second input voltage BV2. When the voltage level of the memory power voltage VDD_M is higher than the voltage level of the reference voltage VREF, the voltage regulator 430 may lower the voltage level of the memory power voltage VDD_M without driving the memory power voltage VDD_M to the second input voltage BV2, for example, by discharging a node from which the memory power voltage is output. The voltage regulator 430 may maintain the voltage level of the memory power voltage VDD_M substantially identically with the voltage level of the reference voltage VREF. The memory power voltage VDD_M generated by the voltage regulator 430 may be supplied and/or distributed to the memory through the memory power supply line 342 as illustrated in FIG. 3.

The monitoring circuit 440 may receive the memory power voltage VDD_M from the voltage regulator 430 and may receive the processor power voltage VDD_P from the main voltage regulator 320 through the processor power supply line 301. The monitoring circuit 440 may monitor the voltage levels of the memory power voltage VDD_M and the processor power voltage VDD_P. The monitoring circuit 440 may generate the voltage adjustment signal MVS by comparing the voltage level of the memory power voltage VDD_M to the voltage level of the processor power voltage VDD_P. The monitoring circuit 440 may include information with regard to a threshold range. For example, the monitoring circuit 440 may store the information with regard to the threshold range as a digital code. A code value of the digital code including the information with regard to the threshold range may be a threshold value. Furthermore, the monitoring circuit 440 may generate a first voltage level signal based on the memory power voltage VDD_M and may generate a second voltage level signal based on the processor power voltage VDD_P. The first and second voltage level signals may each be a digital code signal. The first voltage level signal may have a code value that is changed based on the voltage level of the memory power voltage VDD_M. The second voltage level signal may have a code value that is changed based on the voltage level of the processor power voltage VDD_P. The monitoring circuit 440 may include an analog to digital converter (ADC) that converts an analog voltage into a digital code signal. The monitoring circuit 440 may compute the first and second voltage level signals and may determine whether a difference between the code values of the first and second voltage level signals is greater than the threshold value. When a difference between the code values of the first and second voltage level signals is less than the threshold value, the monitoring circuit 440 may determine that a voltage level difference between the memory power voltage VDD_M and the processor power voltage VDD_P is within the threshold range and might not generate the voltage adjustment signal MVS. When a difference between the code values of the first and second voltage level signals is greater than the threshold value, the monitoring circuit 440 may determine that a voltage level difference between the memory power voltage VDD_M and the processor power voltage VDD_P is outside of the threshold range and may generate the voltage adjustment signal MVS. In this case, when the code value of the second voltage level signal is greater than the code value of the first voltage level signal, the monitoring circuit 440 may generate the voltage adjustment signal MVS capable of raising the voltage level of the memory power voltage VDD_M. When the code value of the second voltage level signal is smaller than the code value of the first voltage level signal, the monitoring circuit 440 may generate the voltage adjustment signal MVS capable of lowering the voltage level of the memory power voltage VDD_M.

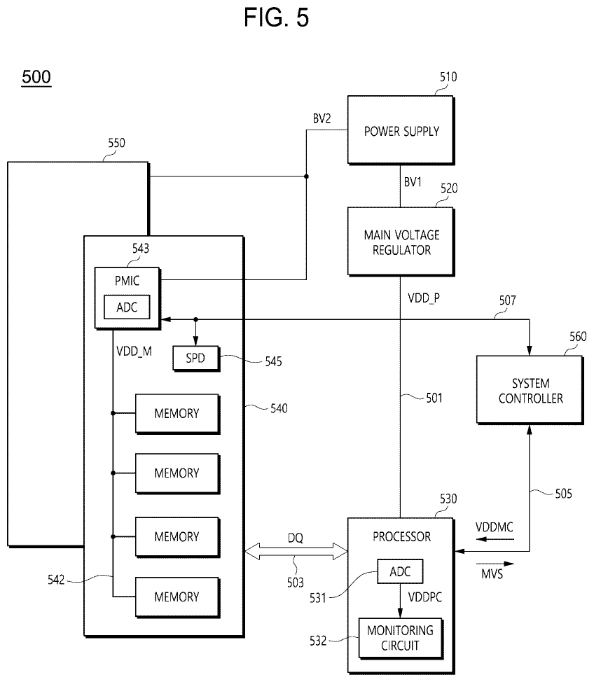

FIG. 5 is a diagram illustrating a configuration of a computing system 500 according to an embodiment. Referring to FIG. 5, the computing system 500 may include a power supply 510, a main voltage regulator 520, a processor 530, and a first memory module 540. Hereinafter, descriptions of the components of the computing system 500 that are identical or redundant to the descriptions of the components of the computing system 300, illustrated in FIG. 3, may be omitted. The power supply 510 may generate a first input voltage BV1 and a second input voltage BV2 by receiving power from an external source. The power supply 510 may provide the first input voltage BV1 to the main voltage regulator 520 and may provide the second input voltage BV2 to the first memory module 540. The main voltage regulator 520 may receive the first input voltage BV1 and may generate a processor power voltage VDD_P from the first input voltage BV1. The main voltage regulator 520 may be coupled to the processor 530 through a processor power supply line 501 and may provide the processor power voltage VDD_P to the processor 530 through the processor power supply line 501.

The processor 530 may communicate with the first memory module 540. The processor 530 may receive the processor power voltage VDD_P from the main voltage regulator 520 through the processor power supply line 501 and may operate by using the processor power voltage VDD_P. The processor 530 may be coupled to the first memory module 540 through a data bus 503, may transmit data DQ to the first memory module 540 through the data bus 503, and may receive data DQ transmitted by the first memory module 540 through the data bus 503. The processor 530 may transmit the data DQ to the first memory module 540 by driving the data bus 503 with the processor power voltage VDD_P.

The first memory module 540 may communicate with the processor 530. The first memory module 540 may receive the second input voltage BV2 and may generate a memory power voltage VDD_M from the second input voltage BV2. The first memory module 540 may operate by using the memory power voltage VDD_M. A target voltage level of the memory power voltage VDD_M may be the same as a target voltage level of the processor power voltage VDD_P. The first memory module 540 may be coupled to the processor 530 through the data bus 503, may transmit the data DQ to the processor 530 through the data bus 503, and may receive the data DQ transmitted by the processor 530 through the data bus 503. The first memory module 540 may transmit the data DQ to the processor 530 by driving the data bus 503 to the memory power voltage VDD_M. The computing system 500 may include one or more memory modules. In an embodiment, the computing system 500 may further include a second memory module 550. The second memory module 550 may have substantially the same configuration as the first memory module 540 and may be coupled to the components of the computing system 500 in substantially the same manner as the first memory module 540. In an embodiment, the computing system 500 may include three or more memory modules.

The processor 530 may monitor the voltage levels of the processor power voltage VDD_P and the memory power voltage VDD_M. The processor 530 may compare the voltage levels of the processor power voltage VDD_P and the memory power voltage VDD_M and may determine whether a voltage level difference between the processor power voltage VDD_P and the memory power voltage VDD_M is within a threshold range. When a voltage level difference between the processor power voltage VDD_P and the memory power voltage VDD_M is within the threshold range, the processor 530 might not perform a function that changes the voltage level of the memory power voltage VDD_M. When a voltage level difference between the processor power voltage VDD_P and the memory power voltage VDD_M falls outside the threshold range, the processor 530 may generate a voltage adjustment signal MVS so that the voltage level of the memory power voltage VDD_M is adjusted. The processor 530 may provide the voltage adjustment signal MVS to the first memory module 540. The first memory module 540 may change a target voltage level of the memory power voltage VDD_M based on the voltage adjustment signal MVS.

The first memory module 540 may generate a first voltage level signal VDDMC based on the memory power voltage VDD_M. The first memory module 540 may generate the first voltage level signal VDDMC including information with regard to the voltage level of the memory power voltage VDD_M. The processor 530 may generate the first voltage level signal VDDMC from the first memory module 540. The processor 530 may generate the second voltage level signal VDDPC based on the processor power voltage VDD_P. The second voltage level signal VDDPC may include information with regard to the voltage level of the processor power voltage VDD_P. The processor 530 may include an ADC 531 capable of generating a second voltage level signal VDDPC from the processor power voltage VDD_P. The processor 530 may compare the first voltage level signal VDDMC to the second voltage level signal VDDPC and may generate the voltage adjustment signal MVS based on the results of comparing the first and second voltage level signals VDDMC and VDDPC. The processor 530 may further include a monitoring circuit 532 that generates the voltage adjustment signal MVS by comparing the first and second voltage level signals VDDMC and VDDPC. The function of the monitoring circuit 532 may be partially the same as the function of the monitoring circuit 440 illustrated in FIG. 4.

The computing system 500 may further include a system controller 560. The system controller 560 may be coupled to the first memory module 540 and the processor 530. The first memory module 540 may transmit the first voltage level signal VDDMC to the system controller 560. The system controller 560 may transmit, to the processor 530, the first voltage level signal VDDMC received from the first memory module 540. The processor 530 may transmit the voltage adjustment signal MVS to the system controller 560. The system controller 560 may transmit, to the first memory module 540, the voltage adjustment signal MVS received from the processor 530. The processor 530 may be coupled to the system controller 560 through a first signal transmission line 505. The first memory module 540 may be coupled to the system controller 560 through a second signal transmission line 507. The first and second signal transmission lines 505 and 507 may use the same communication protocol. The system controller 560 may communicate with the processor 530 and the first memory module 540 through the same communication protocol. The communication protocol may include at least one of the SPI protocol, the I2C protocol, and the I3C protocol. The processor 530, the first memory module 540, and the system controller 560 might not use an additional signal transmission line because the processor 530, the first memory module 540, and the system controller 560 may each perform an operation of reducing a voltage level difference between the memory power voltage VDD_M and the processor power voltage VDD_P by using a communication protocol already included in the computing system 500. Furthermore, the computing system 500 can increase a degree of freedom in designing a system because the monitoring circuit that detects a voltage level difference between the processor power voltage VDD_P and the memory power voltage VDD_M may be selectively disposed in any one of the components of the computing system 500.

The first memory module 540 may include a power management integrated circuit (PMIC) 543 and at least one memory. The PMIC 543 may receive the second input voltage BV2 from the power supply 510. The PMIC 543 may generate the memory power voltage VDD_M from the second input voltage BV2. The PMIC 543 may store memory power voltage setting information with regard to a target voltage level of the memory power voltage VDD_M, for example, VRI in FIG. 4. The PMIC 543 may generate the memory power voltage VDD_M from the second input voltage BV2 based on the memory power voltage setting information. The PMIC 543 may supply the memory power voltage VDD_M to a memory device included in the first memory module 540. The PMIC 543 may provide the memory power voltage VDD_M to the at least one memory device through a memory power supply line 542. The PMIC 543 may generate the first voltage level signal VDDMC based on the memory power voltage VDD_M. The PMIC 543 may include an ADC capable of generating the first voltage level signal VDDMC from the memory power voltage VDD_M. The PMIC 543 may be coupled to the system controller 560 through the second signal transmission line 507. The PMIC 543 may transmit the first voltage level signal VDDMC to the system controller 560 through the second signal transmission line 507.

For example, the first memory module 540 may include four memory devices. The memory devices may be coupled to the PMIC 543 through the memory power supply line 542 and may receive the memory power voltage VDD_M from the PMIC 543 through the memory power supply line 542. The memory devices may operate by using the memory power voltage VDD_M. The data DQ transmitted from the processor 530 to the first memory module 540 through the data bus 503 may be input to the memory devices. The memory devices may store the data DQ. Data output from the memory may be transmitted to the processor 530 through the data bus 503 as the data DQ. The memory devices may drive the data bus 503 with the memory power voltage VDD_M to transmit the data DQ. The first memory module 540 may further include a serial presence detect (SPD) 545. The SPD 545 may be coupled to the system controller 560 through the second signal transmission line 507.

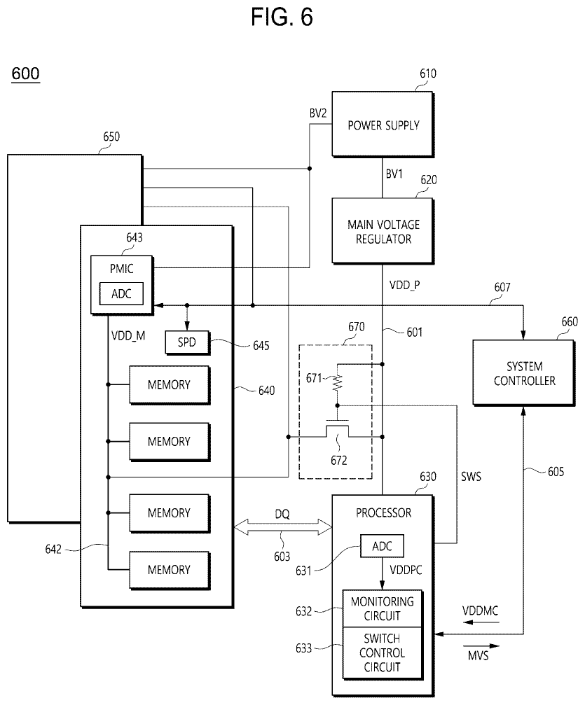

FIG. 6 is a diagram illustrating a configuration of a computing system 600 according to an embodiment. Referring to FIG. 6, the computing system 600 may include a power supply 610, a main voltage regulator 620, a processor 630, a first memory module 640, a system controller 660, and a power switch 670. Hereinafter, descriptions of the components of the computing system 600 that are identical or redundant to the descriptions of the components of the computing system 500, illustrated in FIG. 5, may be omitted. The power supply 610 may generate a first input voltage BV1 and a second input voltage BV2 by receiving power from an external source. The main voltage regulator 620 may generate a processor power voltage VDD_P by receiving the first input voltage BV1. The main voltage regulator 620 may provide the processor power voltage VDD_P to the processor 630 and the power switch 670 through a processor power supply line 601.

The processor 630 may communicate with the first memory module 640. The processor 630 may receive the processor power voltage VDD_P FROM the main voltage regulator 620 through the processor power supply line 601 and may operate by using the processor power voltage VDD_P. The processor 630 may be coupled to the first memory module 640 through a data bus 603, may transmit data DQ to the first memory module 640 through the data bus 603, and may receive data DQ transmitted by the first memory module 640 through the data bus 603. The processor 630 may transmit the data DQ to the first memory module 640 by driving the data bus 603 with the processor power voltage VDD_P.

The first memory module 640 may communicate with the processor 630. The first memory module 640 may receive the second input voltage BV2 and may generate a memory power voltage VDD_M from the second input voltage BV2. The first memory module 640 may operate by using the memory power voltage VDD_M. A target voltage level of the memory power voltage VDD_M may be the same as a target voltage level of the processor power voltage VDD_P. The first memory module 640 may be coupled to the processor 630 through the data bus 603, may transmit the data DQ to the processor 630 through the data bus 603, and may receive the data DQ transmitted by the processor 630 through the data bus 603. The first memory module 640 may transmit the data DQ to the processor 630 by driving the data bus 603 to the memory power voltage VDD_M. The computing system 600 may include one or more memory modules. In an embodiment, the computing system 600 may further include a second memory module 650. The second memory module 650 may have substantially the same configuration as the first memory module 640 and may be coupled to the components of the computing system 600 in substantially the same manner as the first memory module 640.

The processor 630 may monitor the processor power voltage VDD_P and the memory power voltage VDD_M. The processor 630 may compare the voltage level of the processor power voltage VDD_P to the voltage of the memory power voltage VDD_M and may generate a voltage adjustment signal MVS by determining whether a voltage level difference between the processor power voltage VDD_P and the memory power voltage VDD_M is within a threshold range. The processor 630 may further generate a switching signal SWS by detecting a voltage level difference between the processor power voltage VDD_P and the memory power voltage VDD_M. The processor 630 may provide the switching signal SWS to the power switch 670. When a voltage level difference between the processor power voltage VDD_P and the memory power voltage VDD_M is within the threshold range, the processor 630 may enable the switching signal SWS. When a voltage level difference between the processor power voltage VDD_P and the memory power voltage VDD_M is outside of the threshold range, the processor 630 may disable the switching signal SWS.

The first memory module 640 may generate a first voltage level signal VDDMC based on the memory power voltage VDD_M. The processor 630 may generate a second voltage level signal VDDPC based on the processor power voltage VDD_P. The processor 630 may include an ADC 631 capable of generating the second voltage level signal VDDPC from the processor power voltage VDD_P. The processor 630 may further include a monitoring circuit 632 that generates the voltage adjustment signal MVS by comparing the first voltage level signal VDDMC to the second voltage level signal VDDPC. The processor 630 may further include a switch control circuit 633 that generates the switching signal SWS by comparing the first and second voltage level signals VDDMC and VDDPC. In an embodiment, the switch control circuit 633 may be integrated into the monitoring circuit 632. For example, a monitoring circuit including the function of the switch control circuit 633 may enable the switching signal SWS when the voltage adjustment signal MVS is not generated and may disable the switching signal SWS when the voltage adjustment signal MVS is generated.

The system controller 660 may be coupled to the first memory module 640 and the processor 630. The system controller 660 may be coupled to the processor 630 through a first signal transmission line 605 and may be coupled to the first memory module 640 through a second signal transmission line 607. The first memory module 640 may transmit the first voltage level signal VDDMC to the system controller 660 through the second signal transmission line 607. The system controller 660 may transmit the first voltage level signal VDDMC received from the first memory module 640 to the processor 630 through the first signal transmission line 605. The processor 630 may transmit the voltage adjustment signal MVS to the system controller 660 through the first signal transmission line 605. The system controller 660 may transmit the voltage adjustment signal MVS received from the processor 630 to the first memory module 640 through the second signal transmission line 607.

The first memory module 640 may include a power management integrated circuit (PMIC) 643 and at least one memory. The PMIC 643 may receive the second input voltage BV2 from the power supply 610. The PMIC 643 may generate the memory power voltage VDD_M from the second input voltage BV2. The PMIC 643 may store memory power voltage setting information with regard to a target voltage level of the memory power voltage VDD_M. The PMIC 643 may generate the memory power voltage VDD_M from the second input voltage BV2 based on the memory power voltage setting information. The PMIC 643 may supply the memory power voltage VDD_M to memory included in the first memory module 640. The PMIC 643 may provide the memory power voltage VDD_M to the at least one memory through a memory power supply line 642. The PMIC 643 may provide the memory power voltage VDD_M to the power switch 670 through the memory power supply line 642. One of module pins included in the first memory module 640 may be assigned to the PMIC 643, and the PMIC 643 may be coupled to the power switch 670 through the memory power supply line 642 and the assigned module pin. The PMIC 643 may generate the first voltage level signal VDDMC based on the memory power voltage VDD_M. The PMIC 643 may include an ADC that generates the first voltage level signal VDDMC from the memory power voltage VDD_M. The PMIC 643 may be coupled to the system controller 660. The PMIC 643 may transmit the first voltage level signal VDDMC to the system controller 660 through the second signal transmission line 607.

For example, the first memory module 640 may include four memory devices. The memory devices may be coupled to the PMIC 643 through the memory power supply line 642 and may receive the memory power voltage VDD_M from the PMIC 643 through the memory power supply line 642. The memory devices may operate by using the memory power voltage VDD_M. The data DQ transmitted from the processor 630 to the first memory module 640 through the data bus 603 may be input to the memory devices. The memory devices may store the data DQ. Data output from the memory devices may be transmitted to the processor 630 through the data bus 603 as the data DQ. The memory devices may drive the data bus 603 with the memory power voltage VDD_M to transmit the data DQ. The first memory module 640 may further include a serial presence detect (SPD) 645. The SPD 645 may be coupled to the system controller 660 through the second signal transmission line 607.

The power switch 670 may receive the switching signal SWS and may selectively connect the processor power supply line 601 to the memory power supply line 642 based on the switching signal SWS. When the switching signal SWS is enabled, the power switch 670 may be turned on and may connect the processor power supply line 601 to the memory power supply line 642. When the switching signal SWS is disabled, the power switch 670 may be turned off and may electrically separate the processor power supply line 601 and the memory power supply line 642. When a voltage level difference between the memory power voltage VDD_M and the processor power voltage VDD_P is within a threshold range, the switching signal SWS may be enabled, and the power switch 670 may connect the processor power supply line 601 to the memory power supply line 642. As the processor power supply line 601 and the memory power supply line 642 are coupled to each other through the power switch 670, the voltage levels of the memory power voltage VDD_M and the processor power voltage VDD_P may be equalized. For example, when the processor power voltage VDD_P has a higher voltage level than the memory power voltage VDD_M, the power switch 670 may reduce a voltage level difference between the processor power voltage VDD_P and the memory power voltage VDD_M by lowering the voltage level of the processor power voltage VDD_P and raising the voltage level of the memory power voltage VDD_M. In contrast, when the processor power voltage VDD_P has a lower voltage level than the memory power voltage VDD_M, the power switch 670 may reduce a voltage level difference between the processor power voltage VDD_P and the memory power voltage VDD_M by raising the voltage level of the processor power voltage VDD_P and lowering the voltage level of the memory power voltage VDD_M. When a voltage level difference between the memory power voltage VDD_M and the processor power voltage VDD_P falls outside the threshold range, the switching signal SWS is disabled, and the power switch 670 may electrically separate the processor power supply line 601 and the memory power supply line 642. The voltage level of the memory power voltage VDD_M may be adjusted, based on the voltage adjustment signal MVS and the PMIC 643, independent of the voltage level of the processor power voltage VDD_P. After the PMIC 643 adjusts the voltage level of the memory power voltage VDD_M based on the voltage adjustment signal MVS, when the processor 630 determines that a voltage level difference between the memory power voltage VDD_M and the processor power voltage VDD_P is within the threshold range again, the processor 630 may enable the switching signal SWS again. When the switching signal SWS is enabled, the power switch 670 may reduce or minimize a voltage level difference between the processor power voltage VDD_P and the memory power voltage VDD_M by equalizing the voltage levels of the processor power voltage VDD_P and the memory power voltage VDD_M.

The power switch 670 may include a resistance element 671 and a transistor 672. One end of the resistance element 671 may be coupled to the processor power supply line 601. The switching signal SWS may be a signal that is enabled to a logic high level. The transistor 672 may be an N-channel MOS transistor. In an embodiment, the switching signal SWS may be modified as a signal that is enabled to a logic low level. The transistor 672 may be implemented with a P-channel MOS transistor. A gate of the transistor 672 may be coupled to the other end of the resistance element 671 and may receive the switching signal SWS from the processor 630. One of the source and drain of the transistor 672 may be coupled to the processor power supply line 601, and the other of the source and drain of the transistor 672 may be coupled to the memory power supply line 642.

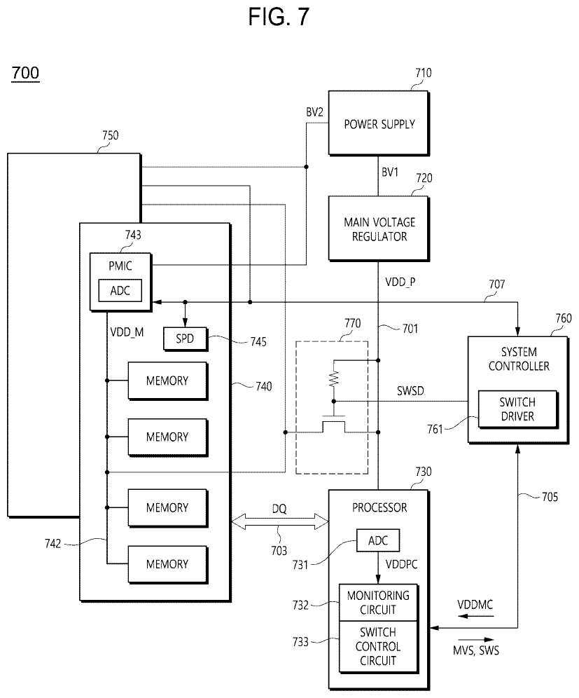

FIG. 7 is a diagram illustrating a configuration of a computing system 700 according to an embodiment. Referring to FIG. 7, the computing system 700 may include a power supply 710, a main voltage regulator 720, a processor 730, a first memory module 740, a system controller 760, and a power switch 770. Hereinafter, descriptions of the components of the computing system 700 that are identical or redundant to the descriptions of the components of the computing system 600, illustrated in FIG. 6, may be omitted. The power supply 710 may generate a first input voltage BV1 and a second input voltage BV2 by receiving power from an external source. The main voltage regulator 720 may generate a processor power voltage VDD_P from the first input voltage BV1. The main voltage regulator 720 may provide the processor power voltage VDD_P to the processor 730 through a processor power supply line 701. The processor 730 may operate by receiving the processor power voltage VDD_P. The processor 730 may be coupled to the first memory module 740 through a data bus 703 and may transmit data DQ to the first memory module 740 by driving the data bus 703 with the processor power voltage VDD_P. The processor 730 may generate a voltage adjustment signal MVS and a switching signal SWS by monitoring a memory power voltage VDD_M and the processor power voltage VDD_P. The first memory module 740 may receive the second input voltage BV2 and may generate the memory power voltage VDD_M from the second input voltage BV2. The first memory module 740 may be coupled to the processor 730 through the data bus 703 and may transmit the data DQ to the processor 730 by driving the data bus 703 to the memory power voltage VDD_M. The first memory module 740 may adjust a target voltage level of the memory power voltage VDD_M based on the voltage adjustment signal MVS. The computing system 700 may further include a second memory module 750 having substantially the same structure as the first memory module 740. The processor 730 may be coupled to the system controller 760 through a first signal transmission line 705. The first memory module 740 may be coupled to the system controller 760 through a second signal transmission line 707.

The first memory module 740 may include a power management integrated circuit (PMIC) 743 and at least one memory device. For example, the first memory module 740 may include four memory devices. The PMIC 743 may receive the second input voltage BV2, may generate the memory power voltage VDD_M from the second input voltage BV2, and may provide the memory power voltage VDD_M to the memory devices through a memory power supply line 742. The PMIC 743 may generate a first voltage level signal VDDMC based on the memory power voltage VDD_M. The first memory module 740 may further include a serial presence detect (SPD) 745 that is coupled to the system controller 760 through the second signal transmission line 707.

The PMIC 743 may transmit the first voltage level signal VDDMC to the system controller 760 through the second signal transmission line 707. The system controller 760 may transmit the first voltage level signal VDDMC to the processor 730 through a first signal transmission line VDDPC. The processor 730 may transmit the voltage adjustment signal MVS to the system controller 760 through the first signal transmission line 705. The system controller 760 may transmit the voltage adjustment signal MVS to the first memory module 740 and the PMIC 743 through the second signal transmission line 707. The processor 730 may transmit the switching signal SWS to the system controller 760 through the first signal transmission line 705.

The power switch 770 may receive a switching driving signal SWSD and may selectively connect the processor power supply line 701 to the memory power supply line 742 based on the switching driving signal SWSD. The power switch 770 may receive the switching driving signal SWSD from the system controller 760 without directly receiving the switching signal SWS from the processor 630 as illustrated in FIG. 6. The computing system 700 may provide the switching signal SWS to the power switch 770 as the switching driving signal SWSD through the system controller 760, without directly providing the switching signal SWS from the processor 730 to the power switch 770. The processor 730 may transmit the switching signal SWS to the system controller 760. The system controller 760 may generate the switching driving signal SWSD by driving the switching signal SWS. The system controller 760 may provide the switching driving signal SWSD to the power switch 770. If the processor 630 directly provides the switching signal SWS to the power switch 670 as illustrated in FIG. 6, a signal transmission line that couples the processor 630 to the power switch 670 needs to be added, and the design of the processor 630 may need to be changed. As illustrated in FIG. 7, if the processor 730 provides the switching signal SWS to the system controller 760 and the system controller 760 provides the switching driving signal SWSD to the power switch 770, the power switch 770 can be efficiently controlled without a burden of changing the design of the processor 730.

The PMIC 743 may include an ADC that generates the first voltage level signal VDDMC based on the memory power voltage VDD_M. The processor 730 may include an ADC 731 that generates the second voltage level signal VDDPC based on the processor power voltage VDD_P. The processor 730 may include a monitoring circuit 732 that generates the voltage adjustment signal MVS by comparing the first voltage level signal VDDMC and the second voltage level signal VDDPC. The processor 730 may include a switch control circuit 733 that generates the switching signal SWS by comparing the first voltage level signal VDDMC and the second voltage level signal VDDPC. The system controller 760 may include a switch driver 761. The switch driver 761 may receive the switching signal SWS from the processor 730 and may generate the switching driving signal SWSD by driving the switching signal SWS. The switch driver 761 may provide the switching driving signal SWSD to the power switch 770.

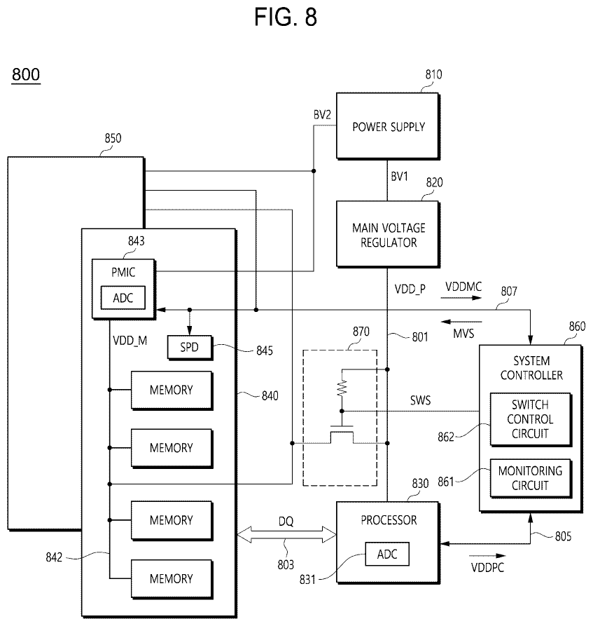

FIG. 8 is a diagram illustrating a configuration of a computing system 800 according to an embodiment. Referring to FIG. 8, the computing system 800 may include a power supply 810, a main voltage regulator 820, a processor 830, a first memory module 840, a system controller 860, and a power switch 870. Hereinafter, descriptions of the components of the computing system 800 that are identical or redundant to the descriptions of the components of the computing system 600, illustrated in FIG. 6, may be omitted. The power supply 810 may generate a first input voltage BV1 and a second input voltage BV2 by receiving power from an external source. The main voltage regulator 820 may generate a processor power voltage VDD_P from the first input voltage BV1. The main voltage regulator 820 may provide the processor power voltage VDD_P to the processor 830 through a processor power supply line 801. The processor 830 may operate by receiving the processor power voltage VDD_P. The processor 830 may be coupled to the first memory module 840 through a data bus 803 and may transmit data DQ to the first memory module 840 by driving the data bus 803 with the processor power voltage VDD_P. The first memory module 840 may receive the second input voltage BV2 and may generate memory power voltage VDD_M from the second input voltage BV2. The first memory module 840 may be coupled to the processor 830 through the data bus 803 and may transmit data DQ to the processor 830 by driving the data bus 803 to the memory power voltage VDD_M. The computing system 800 may further include a second memory module 850 having substantially the same structure as the first memory module 840. The processor 830 may be coupled to the system controller 860 through a first signal transmission line 805. The first memory module 840 may be coupled to the system controller 860 through a second signal transmission line 807.

The first memory module 840 may include a power management integrated circuit (PMIC) 843 and at least one memory. For example, the first memory module 840 may include four memory devices. The PMIC 843 may receive the second input voltage BV2, generate the memory power voltage VDD_M from the second input voltage BV2, and provide the memory power voltage VDD_M to the memory devices through a memory power supply line 842. The first memory module 840 may further include a serial presence detect (SPD) 845 that is coupled to the system controller 860 through the second signal transmission line 807.

The system controller 860 may generate a voltage adjustment signal MVS and a switching signal SWS, based on the memory power voltage VDD_M and the processor power voltage VDD_P. When a voltage level difference between the memory power voltage VDD_M and the processor power voltage VDD_P is within a threshold range, the system controller 860 may enable the switching signal SWS without generating the voltage adjustment signal MVS. When a voltage level difference between the memory power voltage VDD_M and the processor power voltage VDD_P is outside of the threshold range, the system controller 860 may generate the voltage adjustment signal MVS that changes the voltage level of the memory power voltage VDD_M and may disable the switching signal SWS. If the PMIC 343 or the processor 730 generates the voltage adjustment signal MVS or the switching signal SWS by comparing the memory power voltage VDD_M to the processor power voltage VDD_P as illustrated in FIG. 3 or 7, there may be a burden of changing the design of the PMIC 343 or the processor 730. If a function that monitors the memory power voltage VDD_M and the processor power voltage VDD_P is included in the system controller 860, a burden of changing the design of the PMIC or the processor can be reduced.

The PMIC 843 may generate a first voltage level signal VDDMC based on the memory power voltage VDD_M and may provide the first voltage level signal VDDMC to the system controller 860 through the second signal transmission line 807. The processor 830 may generate a second voltage level signal VDDPC based on the processor power voltage VDD_P and may provide the second voltage level signal VDDPC to the system controller 860 through the first signal transmission line 805. The system controller 860 may generate the voltage adjustment signal MVS and the switching signal SWS by comparing the first voltage level signal VDDMC to the second voltage level signal VDDPC. The system controller 860 may provide the voltage adjustment signal MVS to the PMIC 843 of the first memory module 840 through the second signal transmission line 807. The PMIC 843 may adjust the target voltage level of the memory power voltage VDD_M based on the voltage adjustment signal MVS. The system controller 860 may provide the switching signal SWS to the power switch 870. The power switch 870 may receive the switching signal SWS provided by the system controller 860. The power switch 870 may equalize the voltage level of the processor power voltage VDD_P and the voltage level of the memory power voltage VDD_M by selectively electrically coupling the processor power supply line 801 to the memory power supply line 842 based on the switching signal SWS.

The PMIC 843 may include an ADC that generates the first voltage level signal VDDMC based on the memory power voltage VDD_M. The processor 830 may include an ADC 831 that generates the second voltage level signal VDDPC based on the processor power voltage VDD_P. The system controller 860 may include a monitoring circuit 861 that generates the voltage adjustment signal MVS by comparing the first voltage level signal VDDMC to the second voltage level signal and VDDPC. The system controller 860 may include a switch control circuit 862 that generates the switching signal SWS by comparing the first and second voltage level signals VDDMC and VDDPC.

As described above, those skilled in the art to which the present technology pertains may understand that the present technology may be implemented in various other forms without departing from the technical spirit or essential characteristics of the present technology. Accordingly, it is to be understood that the aforementioned embodiments are illustrative from all aspects not being limitative. The scope of the present technology is defined by the appended claims rather than by the detailed description, and all modifications or variations derived from the meanings and scope of the claims and equivalents thereof should be understood as being included in the scope of the present technology.

What is claimed is:

1. A computing system comprising:
a power supply configured to generate a first input voltage and a second input voltage;
a main voltage regulator configured to generate a processor power voltage based on the first input voltage;
a processor configured to receive the processor power voltage; and
a memory module configured to communicate with the processor,
wherein the memory module comprises:
at least one memory device; and
a power management integrated circuit configured to receive the second input voltage and the processor power voltage, to generate a memory power voltage based on the second input voltage and memory power voltage setting information, to provide the memory power voltage to the at least one memory device, and to change the memory power voltage setting information based on comparing the memory power voltage to the processor power voltage.

2. The computing system of claim 1, wherein a target voltage level of the memory power voltage and a target voltage level of the processor power voltage are substantially identical to each other.

3. The computing system of claim 1,
wherein the memory module is coupled to the processor through a data bus,
wherein the memory module is configured to drive the data bus with the memory power voltage, and
wherein the processor is configured to drive the data bus with the processor power voltage.

4. The computing system of claim 1, wherein the power management integrated circuit is configured to maintain the memory power voltage setting information when a voltage level difference between the memory power voltage and the processor power voltage is within a threshold range and configured to modify the memory power voltage setting information when the voltage level difference between the memory power voltage and the processor power voltage is outside of the threshold range.

5. The computing system of claim 1, wherein the power management integrated circuit comprises:
a setting register configured to store the memory power voltage setting information and to change a code value of the memory power voltage setting information based on a voltage adjustment signal;
a reference voltage generator configured to generate a reference voltage based on the second input voltage and the memory power voltage setting information;
a voltage regulator configured to generate the memory power voltage based on the second input voltage, the reference voltage, and the memory power voltage; and
a monitoring circuit configured to receive the memory power voltage and the processor power voltage and to generate the voltage adjustment signal by determining whether a voltage level difference between the memory power voltage and the processor power voltage is greater than a threshold range.

6. The computing system of claim 5, wherein the monitoring circuit is configured to generate the voltage adjustment signal when the voltage level difference between the memory power voltage and the processor power voltage is outside of the threshold range.

7. A computing system comprising:
a power supply configured to generate a first input voltage and a second input voltage;
a main voltage regulator configured to generate a processor power voltage based on the first input voltage;
a processor configured to receive the processor power voltage; and
a memory module configured to communicate with the processor,
wherein the memory module comprises:
at least one memory device; and
a power management integrated circuit configured to generate a memory power voltage based on the second input voltage and memory power voltage setting information, to provide the memory power voltage to the at least one memory device, and to change the memory power voltage setting information based on a voltage adjustment signal, and
wherein the processor is configured to generate the voltage adjustment signal based on the processor power voltage and the memory power voltage.

8. The computing system of claim 7, wherein a target voltage level of the memory power voltage and a target voltage level of the processor power voltage are substantially identical to each other.

9. The computing system of claim 7,
wherein the memory module is coupled to the processor through a data bus,
wherein the memory module is configured to drive the data bus with the memory power voltage, and
wherein the processor is configured to drive the data bus with the processor power voltage.

10. The computing system of claim 7, wherein the processor is configured to generate the voltage adjustment signal when a difference between voltage levels of the processor power voltage and the memory power voltage is outside of a threshold range.

11. The computing system of claim 7,
wherein the power management integrated circuit is configured to generate a first voltage level signal corresponding to a voltage level of the memory power voltage, and
wherein the processor is configured to generate a second voltage level signal corresponding to a voltage level of the processor power voltage and configured to generate the voltage adjustment signal by comparing the first voltage level signal to second voltage level signal.

12. The computing system of claim 11, wherein the processor is configured to generate the voltage adjustment signal when a difference between code values of the first and second voltage level signals is greater than a threshold value.

13. The computing system of claim 11, further comprising a system controller configured to communicate with the processor and the memory module,
wherein the system controller is configured to provide the memory module with the voltage adjustment signal provided by the processor and configured to provide the processor with the first voltage level signal provided by the memory module.

14. The computing system of claim 13, wherein the system controller is configured to communicate with the memory module and the processor through at least one of a serial peripheral interface (SPI) protocol, an inter-integrated circuit (I2C) protocol, and an improved inter-integrated circuit (I3C) protocol.

15. The computing system of claim 7, further comprising a power switch configured to couple a power line through which the memory power voltage is supplied to a power line through which the processor power voltage is supplied, based on a switching signal,
wherein the processor is configured to generate the switching signal based on the memory power voltage and the processor power voltage.

16. The computing system of claim 15, wherein the processor is configured to enable the switching signal when a difference between voltage levels of the memory power voltage and the processor power voltage is within a threshold range and configured to disable the switching signal when the voltage level difference between the memory power voltage and the processor power voltage is outside of the threshold range.

17. The computing system of claim 7, further comprising:
a power switch configured to couple a power line through which the memory power voltage is supplied to a power line through which the processor power voltage is supplied based on a switching driving signal; and
a system controller configured to communicate with the processor and the memory module,
wherein the processor is configured to generate a switching signal based on the memory power voltage and the processor power voltage and configured to provide the switching signal to the system controller, and
the system controller is configured to generate the switching driving signal by driving the switching signal.

18. A computing system comprising:
a power supply configured to generate a first input voltage and a second input voltage;
a main voltage regulator configured to generate a processor power voltage based on the first input voltage;
a processor configured to receive the processor power voltage;
a memory module configured to communicate with the processor; and
a system controller configured to communicate with the processor and the memory module,
wherein the memory module comprises:
at least one memory device; and
a power management integrated circuit configured to generate a memory power voltage based on the second input voltage and memory power voltage setting information, provide the memory power voltage to the at least one memory device, and change the memory power voltage setting information based on a voltage adjustment signal, and
wherein the system controller is configured to generate the voltage adjustment signal based on the processor power voltage and the memory power voltage.

19. The computing system of claim 18, wherein a target voltage level of the memory power voltage and a target voltage level of the processor power voltage are substantially identical to each other.

20. The computing system of claim 18,
wherein the memory module is coupled the processor through a data bus,
wherein the memory module is configured to drive the data bus with the memory power voltage, and
wherein the processor is configured to drive the data bus with the processor power voltage.

21. The computing system of claim 18, wherein the system controller is configured to communicate with the memory module and the processor through at least one of a serial peripheral interface (SPI) protocol, an inter-integrated circuit (I2C) protocol, and an improved inter-integrated circuit (I3C) protocol.

22. The computing system of claim 18, wherein the system controller is configured to generates the voltage adjustment signal when a difference between voltage levels of the memory power voltage and the processor power voltage is outside of the threshold range.

23. The computing system of claim 18,
wherein the power management integrated circuit is configured to generate a first voltage level signal corresponding to a voltage level of the memory power voltage,
wherein the processor is configured to generate a second voltage level signal corresponding to a voltage level of the processor power voltage, and
wherein the system controller is configured to generate the voltage adjustment signal by comparing the first voltage level signal to the second voltage level signal.

24. The computing system of claim 23, wherein the system controller is configured to generates the voltage adjustment signal when a difference between code values of the first and second voltage level signals is greater than a threshold value.

25. The computing system of claim 18, further comprising a power switch configured to couple a power line through which the memory power voltage is supplied to a power line through which the processor power voltage is supplied based on a switching signal,
wherein the system controller is configured to generate the switching signal based on the memory power voltage and the processor power voltage.

26. The computing system of claim 25, wherein the system controller is configured to enable the switching signal when a difference between voltage levels of the memory power voltage and the processor power voltage is within a threshold range and configured to disable the switching signal when the voltage level difference between the memory power voltage and the processor power voltage is outside of the threshold range.
